(19) United States
(12) Patent Application Publication
(10) Pub. No.: US 2008/0210728 A1
(43) Pub. Date: Sep. 4, 2008

(54) SOLAR BACKPACK

(76) Inventor: Jon Bihn, Ardsley, NY (US)

Correspondence Address: MEREDITH & KEYHANI, PLLC, 330 MADISON AVE., 6TH FLOOR, NEW YORK, NY, 10017, US

(21) Appl. No.: 11/775,711

(22) Filed: Jul. 10, 2007

Related U.S. Application Data
(60) Provisional application No. 60/863,366, filed on Oct. 28, 2006.

(51) Int. Cl. A45F 3/04; H01L 31/042; H02J 7/00; H02M 1/00

(52) U.S. Cl. 224/576; 136/244; 320/101; 363/178

(57) ABSTRACT

A solar backpack comprising: a backpack; a solar panel assembly attached to the top half of the backpack, wherein the solar panel assembly protrudes at an angle between 5 and 45 degrees above the front portion of the backpack to allow the user to walk and charge their batteries at the same time; a battery contained in the backpack and in electrical communication with the solar panel; an interchangeable battery recharge cord for recharging external battery operated devices.

This patent claims priority to provisional patent 60/863,366 filed Oct. 28, 2006 and patent application Ser. No. 29/247,862 filed on Jul. 17, 2006.

The present invention relates generally to backpacks and more specifically to high efficiency solar backpacks.

Dependence on oil and foreign resources of oil has led to many problems. Also, it is becoming increasingly clear that the use of certain types of energy is harmful to our environment. Because of these problems, many people are trying to reduce consumption of energy.

Another problem that has led to the creation of the present invention is the use of cell phones, pda's, laptop and other battery powered devices. Such devices often run out of battery power when away from home and lacking an electricity source. In the event we are in danger or an emergency exists we are rendered helpless without power. This may be solved by carrying plugs, battery powered rechargers and purchasing extra batteries. However, this can be cumbersome carrying plug for each device. For example, the user may have to carry a car charger for their phone, an extra plug for their pda and another plug for their laptop. Because of this, it is desirable to provide a solar powered backpack that may be used to recharge and/or power cell phones, pda's, laptop and other battery powered devices. Another problem is that a solar panel assembly that lies flat on the back requires the user to remove the backpack and lie it down to draw power. The present invention is capable of being used while the user is walking around town with the backpack on their back.

Accordingly, the present invention provides a backpack that utilizes solar panels to provide power to a variety of personal devices.

### SUMMARY OF THE INVENTION

The present invention relates generally to backpacks, and in particular solar powered backpacks.

According to a first embodiment, a solar backpack is disclosed comprising: a backpack; a solar panel assembly attached to the top half of the backpack bag, wherein the solar panel assembly protrudes at an angle between 5 and 45 degrees above the front top portion of the backpack bag; a battery contained in the backpack bag and in electrical communication with the solar panel; an interchangeable battery recharge cord in electrical communication with the battery for recharging at least one external apparatus.

According to another aspect of the present invention, a solar backpack is disclosed comprising: a backpack; an angled flap attached to the front top portion of the backpack; a solar panel assembly attached to the angled flap on the top half of the backpack bag, wherein the solar panel assembly protrudes at an angle between 5 and 45 degrees above the front top portion of the backpack bag; a battery contained in the backpack bag and in electrical communication with the solar panel; an interchangeable battery recharge cord in electrical communication with the battery for recharging at least one external apparatus.

A solar backpack comprising: a backpack having a bottom bucket portion and a top flap enclosure; a solar panel assembly attached to the top flap enclosure of the backpack bag, wherein the solar panel assembly protrudes at an angle between 5 and 45 degrees from the bottom bucket portion of the backpack bag; a battery contained in the backpack bag and in electrical communication with the solar panel; an interchangeable battery recharge cord in electrical communication with the battery for recharging at least one external apparatus.

These and other features, aspects and advantages of the present invention will become better understood with reference to the following description and claims.

### BRIEF DESCRIPTION OF THE DRAWINGS

FIG. 1 depicts the present invention;

FIG. 2 depicts the present invention;

FIG. 3 depicts the present invention;

FIG. 4 depicts the present invention;

FIG. 5 depicts the present invention;

FIG. 6 depicts the present invention;

FIG. 7 depicts the present invention;

FIG. 8 depicts the present invention;

FIG. 9 depicts the present invention;

FIG. 10 depicts the present invention; and

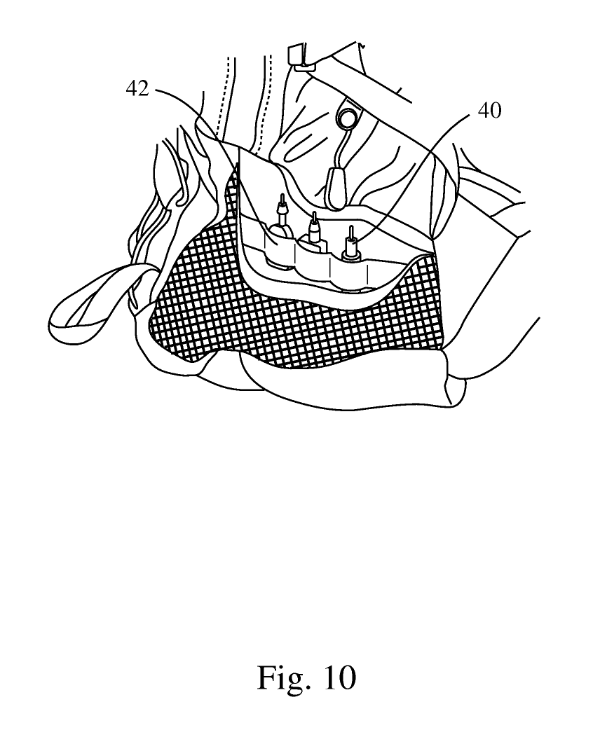

FIG. 11 depicts the present invention.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

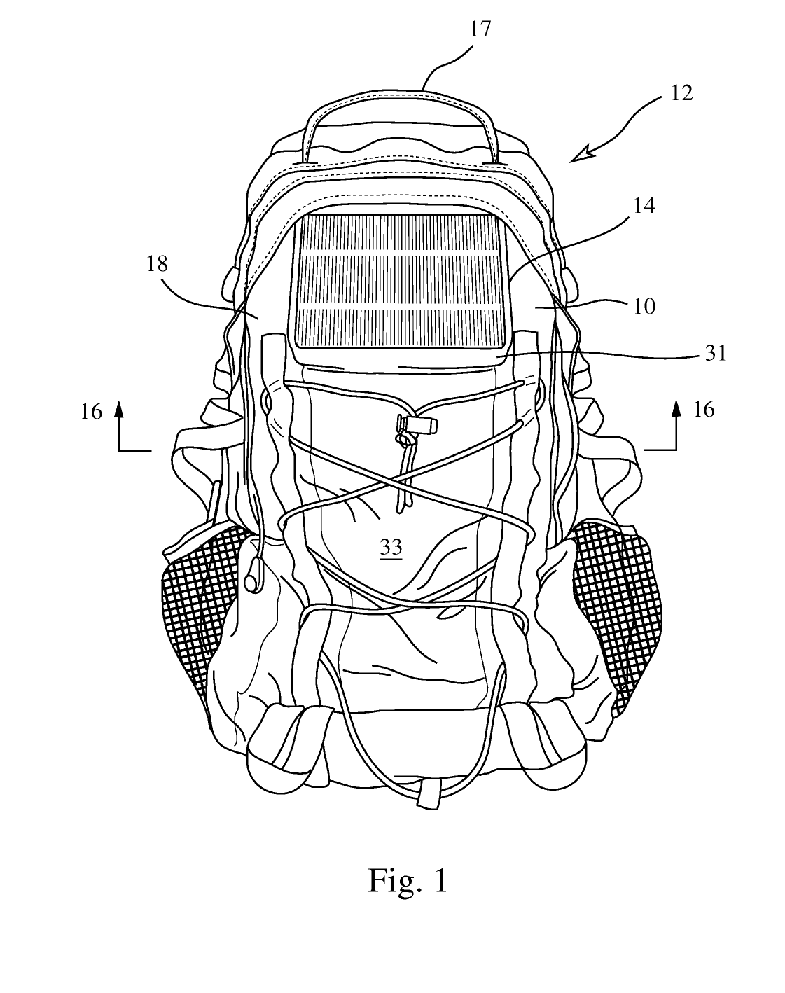

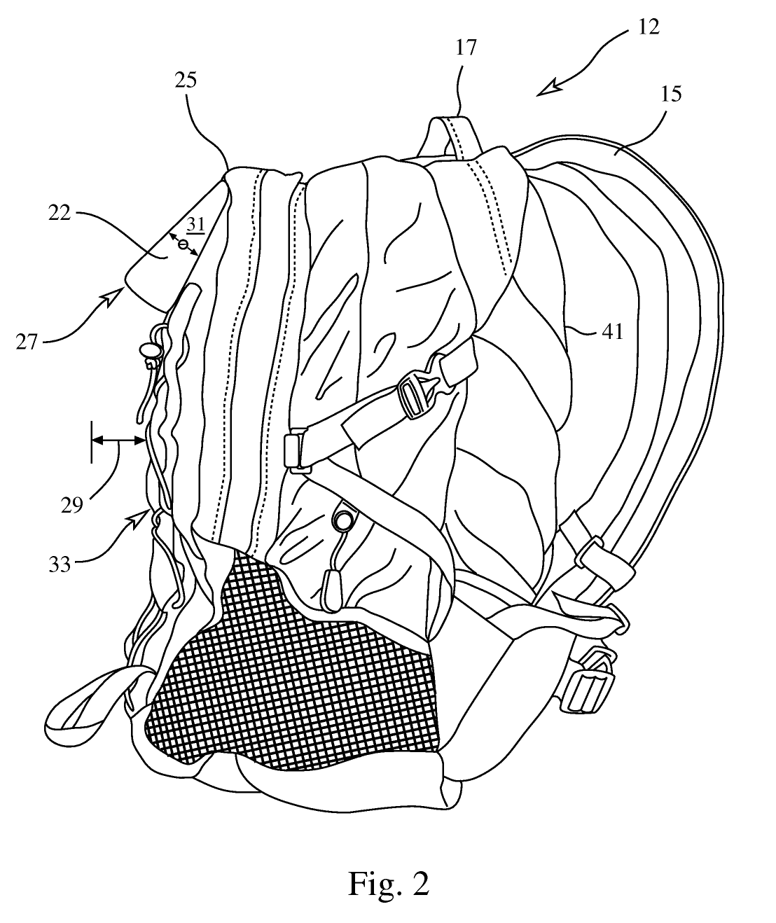

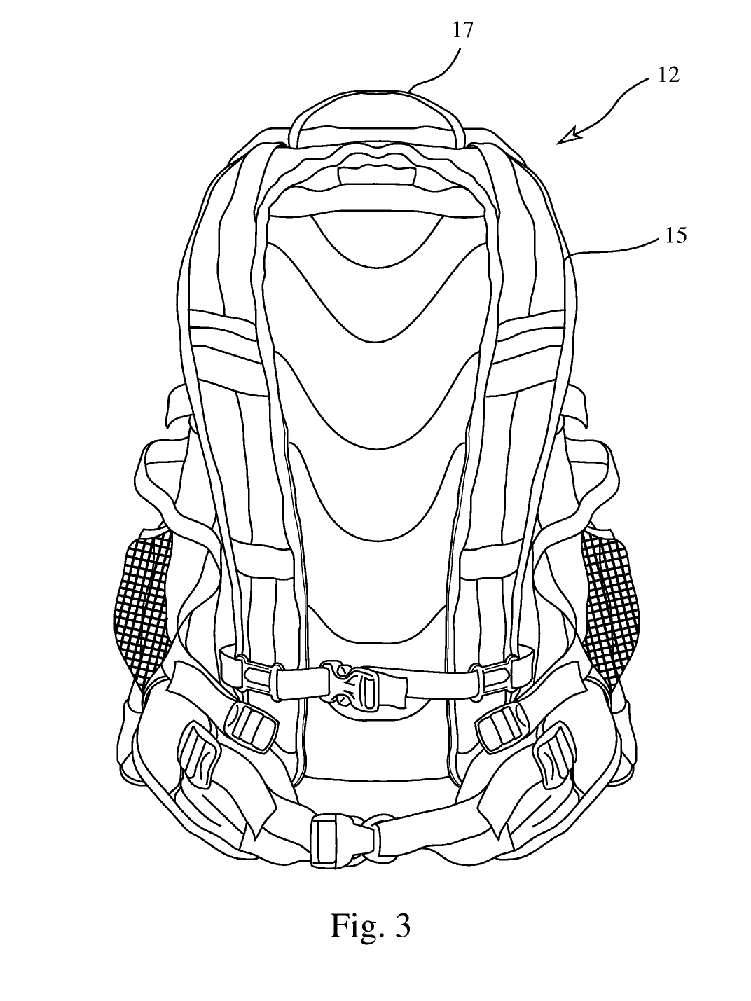

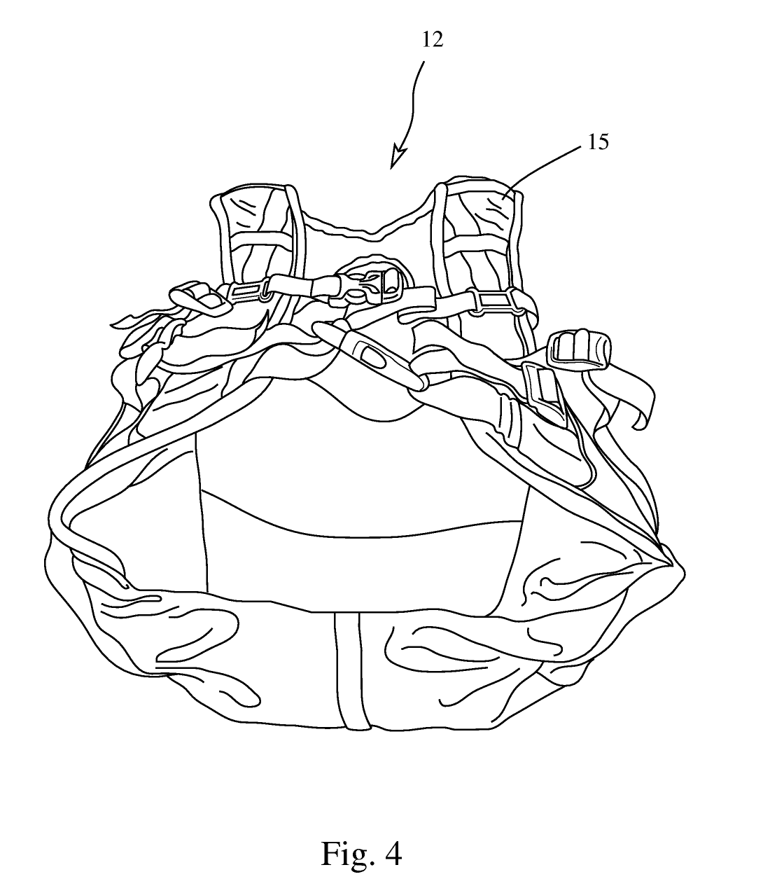

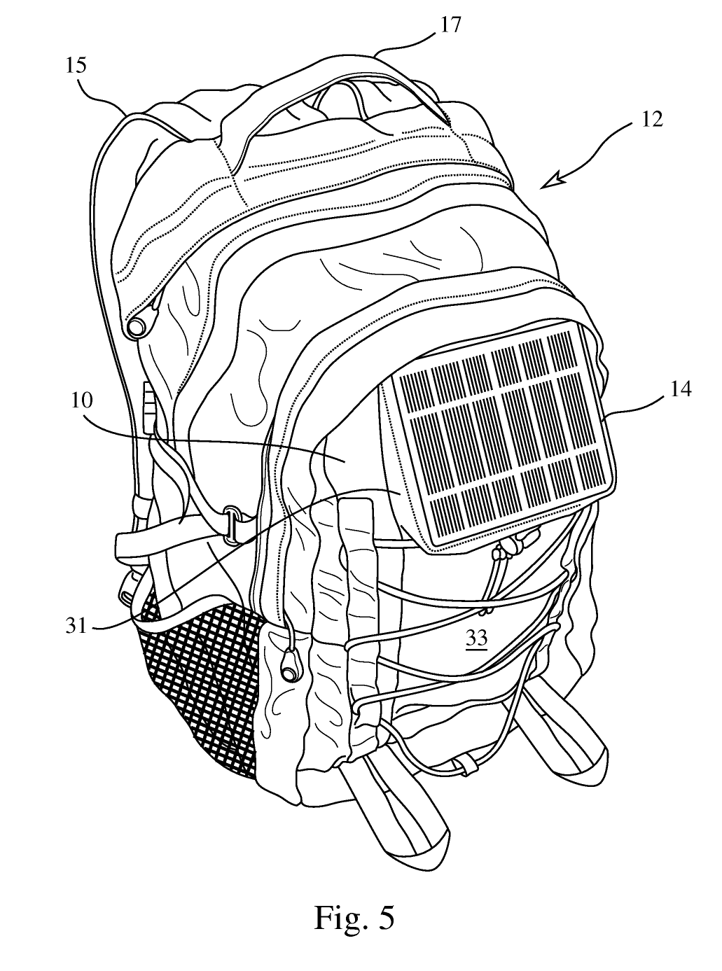

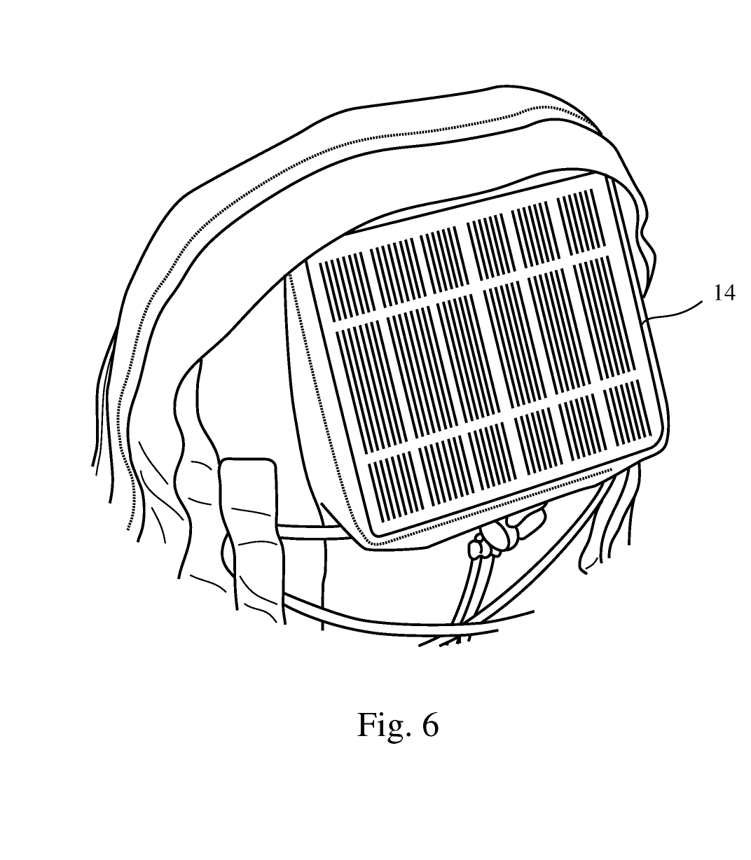

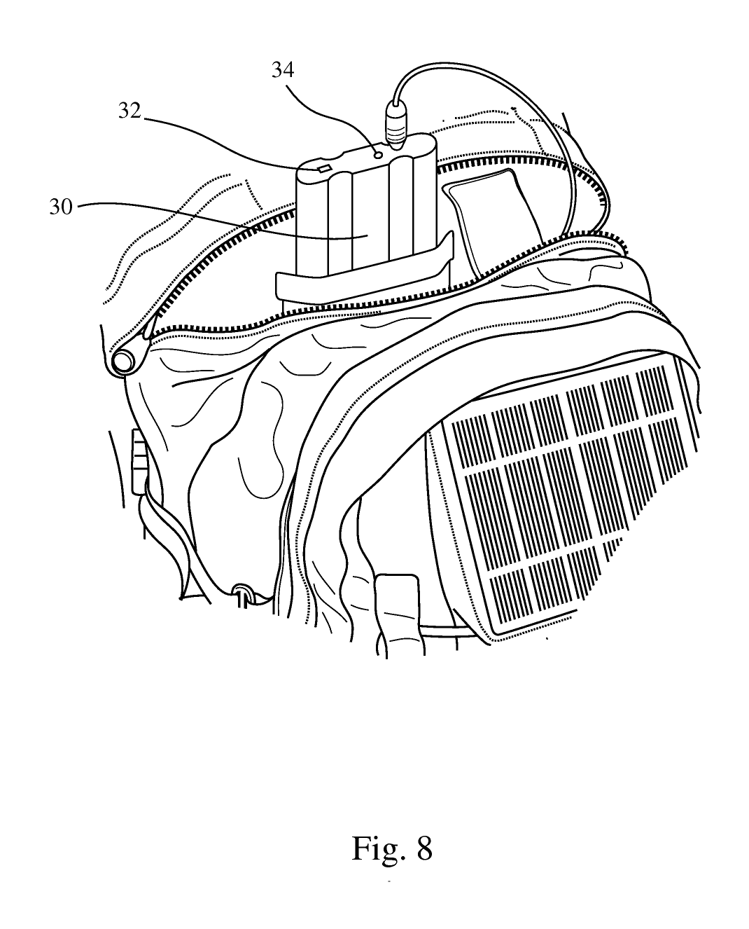

Turning to FIGS. 1-9, a solar backpack (12) is disclosed, the solar backpack comprising: a backpack portion (10); a solar panel assembly (14) attached to the top half (16) of the solar backpack (12), wherein the solar panel assembly (14) protrudes at an angle (22) between 5 and 45 degrees above the front top portion (18) of the solar backpack (12); a battery contained in the backpack bag and in electrical communication with the solar panel; an interchangeable battery recharge cord in electrical communication with the battery for recharging at least one external apparatus. A plastic cover (38), wherein the plastic cover (38) is in communication with the solar panel assembly (14).

The top (25) of the solar panel assembly (14) is flush with and attached to the top half (16) of the backpack and the bottom (27) of the solar panel assembly (14) protrudes (29) between one and three inches from the backpack to form an angle (22) between 20 and 45 degrees. The solar panel assembly (14) may have an angled flap (31) for supporting the solar panel assembly (14) above the front (33) of the backpack. The backpack, as shown has a top handle (17), and backpack straps 5.

The solar panel assembly (14) may be made from a tough, 600D poly and padded with foam. According to one embodiment, the foam may be contained behind the solar panel assembly (14) and in communication with the angled flap (31). It weighs approximately 0.78 kg, including the solar panel (14) and the battery (30), and has a capacity of approximately 0.03 cubic meters. The battery (30) has a voltage converter switch (32) on the top of the battery (30) allows you to adjust the power output to suit the device being charged 5V,6V or 7.2V volts. The 5V setting is useful for devices like USB charges, cell phones, most PDA's Some cell phones use at 6V. Larger digital cameras run at 7.2V. To save power, it is recommended to put the switch at the 7.2V position when the power bank is not in use. There is a LED light (34) on the face of the battery that indicates the battery is receiving a charge. It is designed to use four type of power: 600 mAh Ni-Mh, 900 mAh Li-ion and 1700 mAh Li-ion battery.

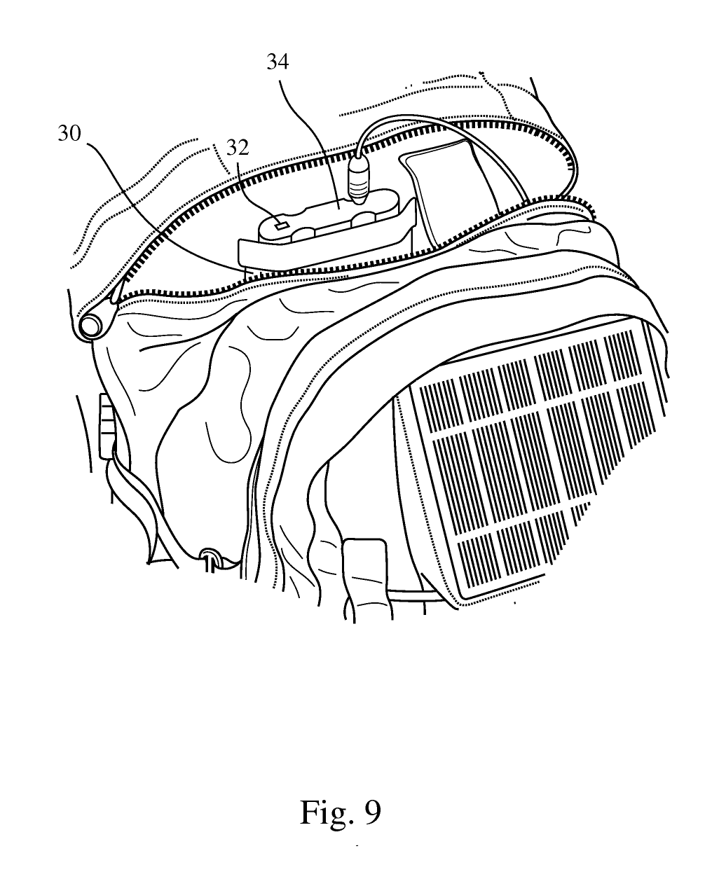

The battery (30) pack clips inside the back pocket of the bag, and can be removed and used separately, as shown in FIG. 9. It is also sold separately with standard adaptors and chargers.

Specification:

| Output Voltage | AT: | 5 V | | 6 V | | 7.2 V | |
|---|---|---|---|---|---|---|---|
| Output | | 300-500 | mA | 300-500 | mA | 300-500 | mA |
| Current | | | | | | | |
| Output | Ni-Mh | 860 | mAh | 720 | mAh | 600 | mAh |
| Capacity | Li-Ion | 1290 | mAh | 1080 | mAh | 900 | mAh |
| | | 2440 | mAh | 2040 | mAh | 1700 | mAh |

Common Specifications:

| | |
|---|---|
| Input Power | Min. 9 V~Max. 11 V/800 mA |
| Charge Current | Max. 500 mA |
| Charge Time | DC charges 2-4 hours; car charges 1-2 hours. |
| (Charge power | Solar 8-16 hours in direct sun light |
| bank) | |
| Battery Type | Li-Ion/Ni-Cd/Ni-Mh |
| Protection | Short, Over Charge, Over Discharge, Over Current, |
| | Over Temp |
| Weight | 110 g |
| Dimensions | 82 × 70 × 15 mm |

There may also be an external battery charger, such as a car charger and/or DC charger to charge the battery (30) directly. These are not used to charge the phone directly. Included with the backpack are a set of standard adaptors (40). The standard adaptors (40) may be stored in an internal compartment (42). To charge a device you can use a standard car charger, or a USB charger. There are also direct adaptors for popular cell phones, and a set of universal adaptors (40). There may also be an AC travel charger and a car charger for charging the power bank when solar charging is not practical. In addition to these standard items, there are a range of optional adaptors for cell phones, PDA's etc.

Integrating the solar panel into the top of the solar pack is a key innovation of the solar pack. It means that unlike a typical solar charger: There is no need to unpack and setup the panel, there is no need to stay in one place, all of the devices can stay securely inside the pack. These solar panels use single crystalline silicon to provide efficient and lightweight portable solar sources to recharge batteries and equipment in the field. It is built into the top of the solar pack, so the pack itself does not feel stiff or restrictive. It's life span is 3˜5 years. It generates up to 1 watt of power, enough to charge most portable electronics (other than laptops). A cell phone will take 3-5 hours to charge.

Specifications

| | |
|---|---|
| Panel Dimensions | 80 × 110 mm |
| Weight | 40 g |
| Substrate Type | 2 mm Poly/Plastic |
| Substrate Color | Blue |
| Cell Type | Mono-crystalline |
| Cell Efficiency | 14.5~15.5% |
| Peak Voltage | ≧10 V |
| Peak Current | ≧100 mA |

The Solar Backpack is a special travel backpack with a multi-function charger. So whether you are walking the beach, on a picnic, nature walk, mountain trails and even sailing or boating, the solar backpack never stops working. It turns solar into power for your mobile phone and all kinds of digital devices. Once you take solar backpack with you, you are walking with power on your back. Because of this you may want a rain cover. The rain cover would be see through and slightly larger than the backpack to protect the backpack. The solar panel may be under plastic, however, it would still be desirable to protect your phones, chargers and electronic assembly associated with the battery. The rain cover would protect the entire bag and its contents.

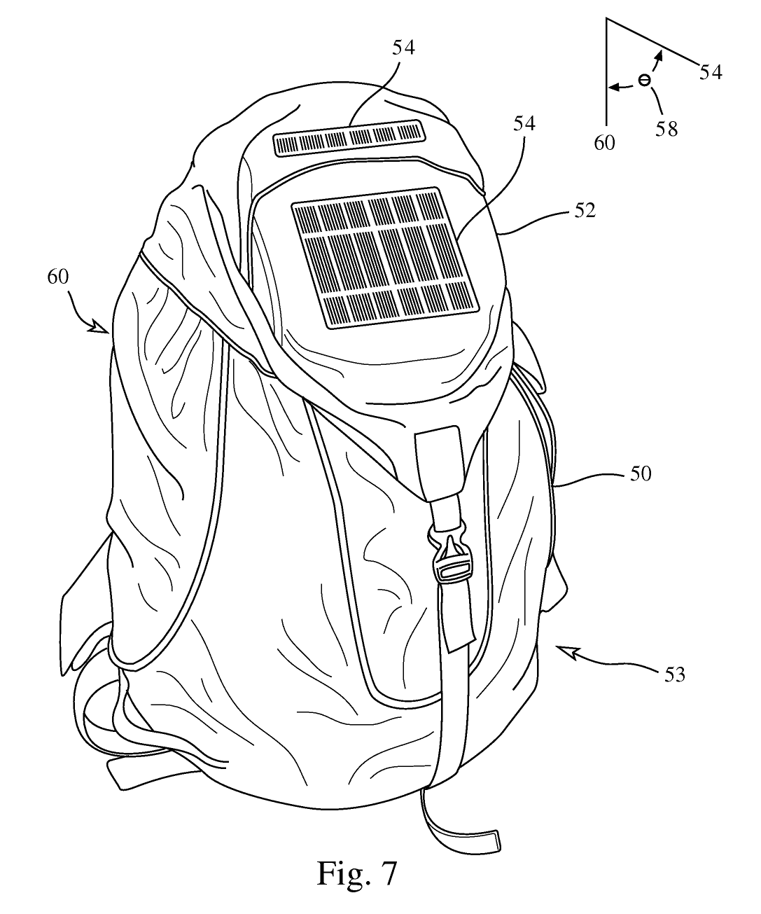

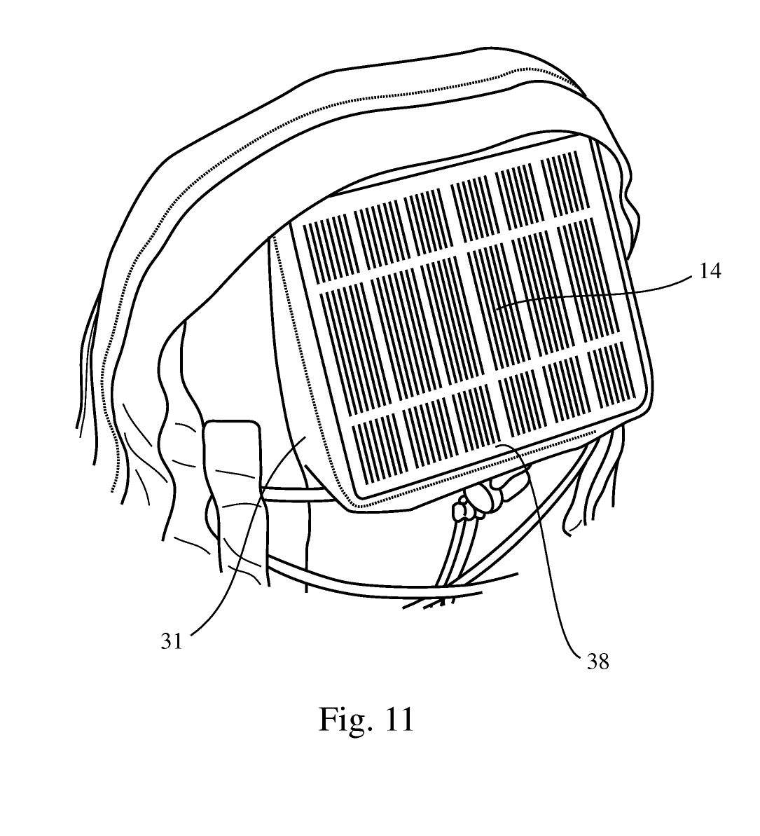

FIG. 7 depicts another embodiment according to the present invention. It is intended to depict an embodiment utilizing a top flap (52) as the method of pointing the solar assembly towards the sun, to avoid having to remove the backpack for it to charge the external device and allow the user to charge their cell phone etc. while walking down the street. According to this embodiment, the solar backpack (53) is a backpack having a bottom bucket portion (50) and a top flap (52) enclosure. The top flap (52) enclosure is above the midpoint or middle of the backpack. The solar panel assembly (54) is attached to the top flap (52) enclosure of the backpack bag. The solar panel assembly (54) may sit on the top flap and be substantially perpendicular to the portion of the backpack that rests on the users back, the back portion (60). The solar panel assembly (54) may be at an angle between 95 and 81 degrees from the back portion (60) of the backpack bag. The top flap (52) may also have a protruding solar panel (54) assembly with an angled flap (80), as shown in FIG. 11. The addition of a an angled flap (80) to any of the different types of backpacks (including the bucket bottom bag) allows for the greatest solar angle and lifts the solar panel away from the user and the backpack to achieve increased solar energy. A battery (30) contained in the solar backpack is in electrical communication with the solar panel assembly (54). There may also be an interchangeable battery recharge cord in electrical communication with the battery for recharging at least one external apparatus. There may be a plastic cover (38) in communication with the solar panel assembly (54).

It should be understood that the foregoing relates to preferred embodiments of the invention and that modifications may be made without departing from the spirit and scope of the invention as set forth in the following claims.

I claim:

1. A solar backpack comprising:
a backpack portion;
at least one solar panel assembly attached to the top half of said backpack portion, wherein said solar panel assembly protrudes at an angle between 5 and 45 degrees above the front top portion of said solar backpack;
a battery contained in said backpack portion and in electrical communication with said solar panel assembly;
an interchangeable battery recharge cord in electrical communication with said battery for recharging at least one external apparatus.

2. A solar backpack as in claim 1, further comprising a plastic cover, wherein said plastic cover is in communication with said solar panel assembly.

3. A solar backpack as in claim 1, wherein said top of said solar panel assembly is flush with and attached to the top half of said backpack and the bottom of said solar panel assembly protrudes between one and three inches from said backpack portion to form an angle between 20 and 45 degrees.

4. A solar backpack as in claim 1, wherein said solar panel assembly is further comprised of an angled flap for supporting said solar panel assembly above the front of said backpack portion.

5. A solar backpack as in claim 1, further comprising a rain cover, wherein said rain cover is slightly larger than said backpack to protect said backpack.

6. A solar backpack as in claim 1, further comprising a voltage converter switch in communication with said battery.

7. A solar backpack as in claim 7, wherein said voltage converter switch adjusts the power output to 5V, 6V or 7.2V volts

8. A solar backpack as in claim 1, further comprising a battery charger.

9. A solar backpack comprising:
a backpack portion;
an angled flap attached to the front top portion of said backpack portion;
at least one solar panel assembly attached to said angled flap on the top half of said backpack portion, wherein said solar panel assembly protrudes at an angle between 5 and 45 degrees above the front top portion of said backpack portion;
a battery contained in said backpack and in electrical communication with said solar panel;
an interchangeable battery recharge cord in electrical communication with said battery for recharging at least one external apparatus.

10. A solar backpack as in claim 9, further comprising a plastic cover, wherein said plastic cover is in communication with said solar panel assembly.

11. A solar backpack as in claim 9, wherein said top of said solar panel assembly is flush with and attached to the top half of said backpack portion and the bottom of said solar panel assembly protrudes between one and three inches from said backpack portion to form an angle between 20 and 45 degrees.

12. A solar backpack as in claim 9, wherein said solar panel assembly is further comprised of an angled flap for supporting said solar panel assembly above the front of said backpack.

13. A solar backpack as in claim 9, further comprising a rain cover, wherein said rain cover is slightly larger than said backpack to protect said backpack.

14. A solar backpack as in claim 9, further comprising a rain cover, wherein said rain cover is slightly larger than said backpack to protect said backpack.

15. A solar backpack as in claim 9, further comprising a voltage converter switch in communication with said battery.

16. A solar backpack as in claim 9, wherein said voltage converter switch adjusts the power output to 5V, 6V or 7.2V volts

17. A solar backpack comprising:
a backpack having a back portion, bottom bucket portion and a top flap enclosure, wherein said top flap enclosure is above the midpoint of said backpack;
at least one solar panel assembly attached to the top flap enclosure of said backpack bag, wherein said solar panel assembly is at an angle between 95 and 81 degrees from said back portion of said backpack bag;
a battery contained in said backpack bag and in electrical communication with said solar panel;
an interchangeable battery recharge cord in electrical communication with said battery for recharging at least one external apparatus.

18. A solar backpack as in claim 17, wherein said solar panel assembly (54) may sit on the top flap and be substantially perpendicular to the portion of the backpack that rests on the users back.

19. A solar backpack as in claim 17, further comprising a plastic cover, wherein said plastic cover is in communication with said solar panel assembly.

20. A solar backpack as in claim 17, wherein said solar panel assembly is further comprised of an angled flap for supporting said solar panel assembly above the front of said backpack.

21. A solar backpack as in claim 17, further comprising an internal compartment for storing adapters and said battery.

22. A solar backpack as in claim 17, further comprising a rain cover, wherein said rain cover is slightly larger than said backpack to protect said backpack.

23. A solar backpack as in claim 17, further comprising a voltage converter switch in communication with said battery.

24. A solar backpack as in claim 18, wherein said voltage converter switch adjusts the power output to 5V, 6V or 7.2V volts
